(19) United States
(12) Patent Application Publication
(10) Pub. No.: US 2026/0101501 A1
(43) Pub. Date: Apr. 9, 2026

(54) SEMICONDUCTOR MEMORY DEVICE AND METHOD FOR MANUFACTURING THE SAME

(71) Applicant: SAMSUNG ELECTRONICS CO., LTD., Suwon-si (KR)

(72) Inventors: Soo Ho SHIN, Suwon-si (KR); Ji Hoon CHANG, Suwon-si (KR); Dong-Sik PARK, Suwon-si (KR)

(73) Assignee: SAMSUNG ELECTRONICS CO., LTD., Suwon-si (KR)

(21) Appl. No.: 19/211,014

(22) Filed: May 16, 2025

(30) Foreign Application Priority Data
Oct. 7, 2024 (KR) 10-2024-0135370

(51) Int. Cl. H10B 12/00

(52) U.S. Cl. CPC H10B 12/485; H10B 12/0335; H10B 12/315; H10B 12/34; H10B 12/50

(57) ABSTRACT

A semiconductor memory device includes a substrate including a first area and a second area arranged along a first direction, an active pattern disposed in the first area and including a first portion and a second portion, a gate electrode extending in a second direction intersecting the first direction, the gate electrode crossing between the first portion and the second portion, a conductive pattern disposed on the substrate and connected to the first portion, the conductive pattern extending in the first direction, and having an end on the second area, a buried contact disposed on a side surface of the conductive pattern on the first area to connect to the second portion, a capacitor structure connected to the buried contact, and an edge insulating film disposed on the side surface of the conductive pattern on the second area, the edge insulating film surrounding the end of the conductive pattern.

### CROSS-REFERENCE TO RELATED APPLICATION

This application claims priority from Korean Patent Application No. 10-2024-0135370 filed on Oct. 7, 2024 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a semiconductor memory device and a method for manufacturing the same. More specifically, the present disclosure relates to a semiconductor memory device including a capacitor and a method for manufacturing the same.

### Description of Related Art

As a semiconductor memory device becomes increasingly highly integrated, individual circuit patterns are becoming smaller to implement a large number of semiconductor memory devices in the same area. However, the miniaturization of the individual circuit patterns increases a difficulty level of a process and causes defects.

### SUMMARY

Aspects of the present disclosure provide a semiconductor memory device with improved yield and productivity.

Aspects of the present disclosure also provide a method for manufacturing a semiconductor memory device capable of manufacturing a semiconductor memory device with improved yield and productivity.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor memory device comprising a substrate including a first area and a second area arranged along a first direction, an active pattern disposed in the first area and including a first portion and a second portion, a gate electrode extending in a second direction intersecting the first direction, the gate electrode crossing between the first portion and the second portion, a conductive pattern disposed on the substrate and connected to the first portion, the conductive pattern extending in the first direction, and having an end on the second area, a buried contact disposed on a side surface of the conductive pattern on the first area, the buried contact connecting to the second portion, a capacitor structure connected to the buried contact, and an edge insulating film disposed on the side surface of the conductive pattern on the second area, the edge insulating film surrounding the end of the conductive pattern, wherein the edge insulating film includes a seam extending in the first direction.

According to an aspect of the present disclosure, there is provided a semiconductor memory device comprising a substrate including a first area and a second area arranged along a first direction, an active pattern disposed in the first area and including a first portion and a second portion, a gate electrode extending in a second direction intersecting the first direction, the gate electrode crossing between the first portion and the second portion, a conductive pattern disposed on the substrate and connected to the first portion, the conductive pattern extending in the first direction, and having an end on the second area, a spacer structure disposed on and extending along a side surface of the conductive pattern, a buried contact disposed on the spacer structure on the first area, the buried contact connecting to the second portion, a capacitor structure connected to the buried contact, and an edge insulating film disposed on the spacer structure on the second area, wherein a portion of the spacer structure is interposed between the substrate and the edge insulating film.

According to an aspect of the present disclosure, there is provided a semiconductor memory device comprising a substrate including a cell area and a peripheral area around the cell area, wherein the cell area comprises a first area and a second area interposed between the first area and the peripheral area in a first direction, an active pattern disposed in the first area and including a first portion and a second portion, a gate electrode extending in a second direction intersecting the first direction, the gate electrode crossing between the first portion and the second portion, a first conductive line disposed on the substrate and connected to the first portion, the first conductive line extending in the first direction, a second conductive line disposed on the substrate and extending in the first direction, the second conductive line being spaced apart from the first conductive line in the second direction, a buried contact disposed between the first conductive line and the second conductive line and connecting the second portion, a capacitor structure connected to the buried contact, and an edge insulating film disposed on the second area, wherein the first conductive line comprises a first line portion disposed on the first area and a first edge portion disposed on the second area and having an end of the first conductive line, wherein the second conductive line comprises a second line portion disposed on the first area, and a second edge portion disposed on the second area and having an end of the second conductive line, the second edge portion protruding beyond the first edge portion toward the peripheral area, wherein the edge insulating film comprises a first filling portion interposed between the first edge portion and the second edge portion in the second direction, and a second filling portion overlapping the first edge portion in the first direction and overlapping the second edge portion in the second direction.

### BRIEF DESCRIPTION OF DRAWINGS

The above and other aspects and features of the present disclosure will become more apparent by describing in detail embodiments thereof with reference to the attached drawings, in which:

FIG. 1 is an example block diagram illustrating a semiconductor memory device according to some embodiments;

FIG. 2 is an example layout diagram illustrating an R area of FIG. 1;

FIG. 3 is a cross-sectional view taken along lines A1-A1 and A2-A2 of FIG. 2;

FIG. 4 is a cross-sectional view taken along line B-B of FIG. 2;

FIG. 5 is a partial layout diagram illustrating a semiconductor memory device according to some embodiments;

FIG. 6 is a partial layout diagram illustrating a semiconductor memory device according to some embodiments;

FIG. 7 is a cross-sectional view taken along line A2-A2 of FIG. 6; and

FIG. 8 to FIG. 48 are diagrams of intermediate structures corresponding to intermediate steps of a method for manufacturing a semiconductor memory device according to some embodiments.

### DETAILED DESCRIPTIONS

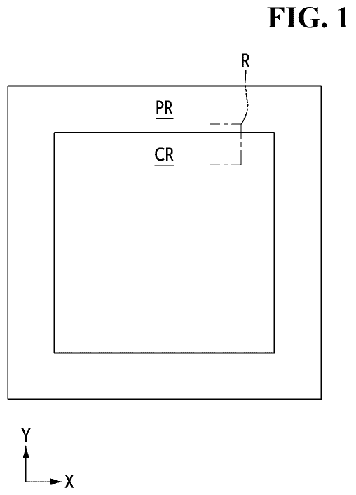

Hereinafter, with reference to FIGS. 1 to 7, a semiconductor memory device according to some embodiments is described.

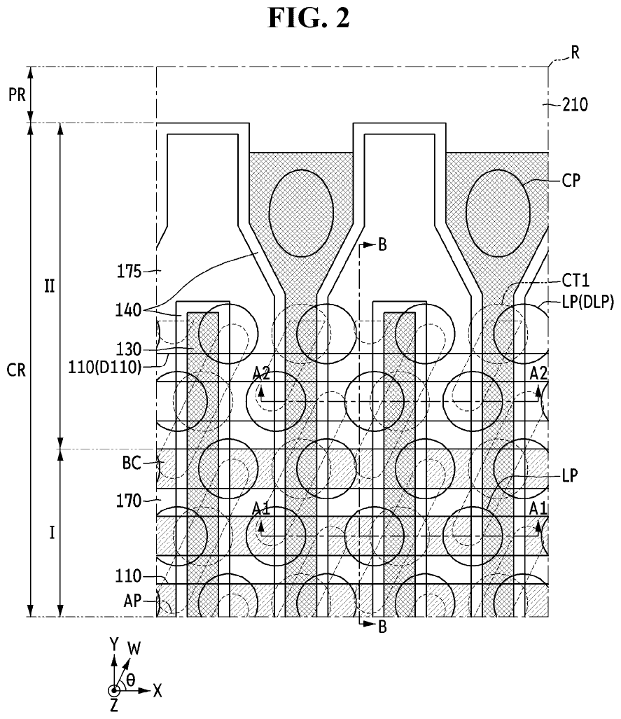

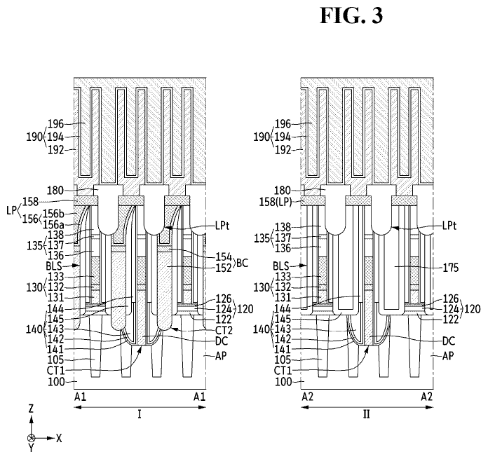

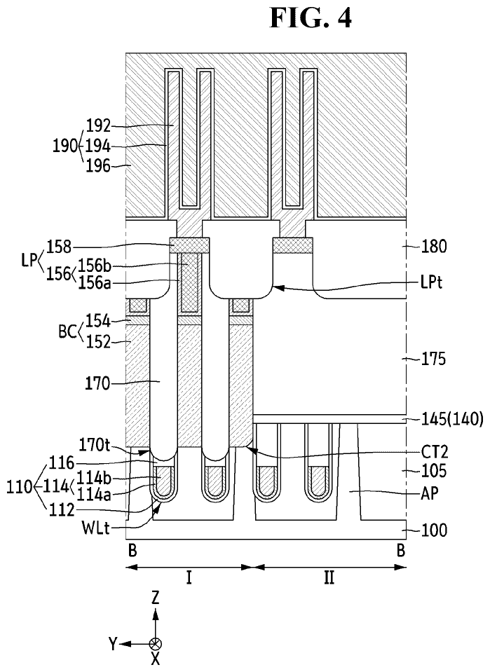

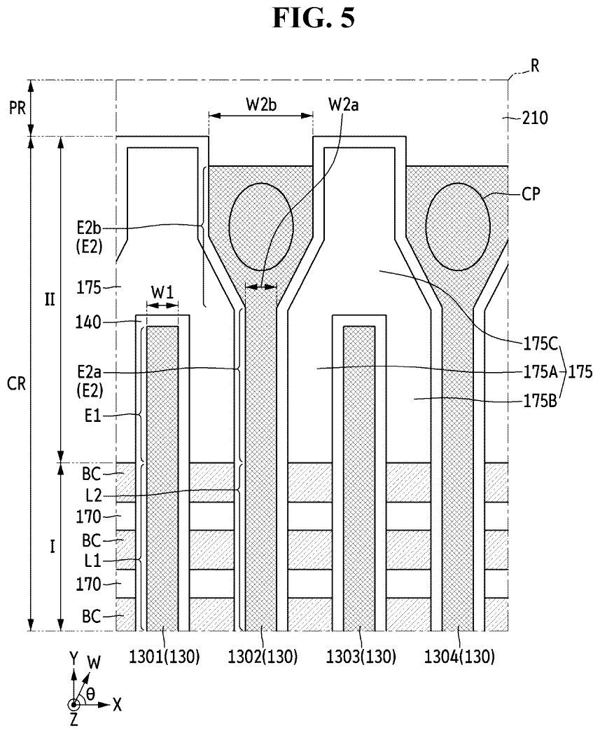

FIG. 1 is an example block diagram illustrating a semiconductor memory device according to some embodiments. FIG. 2 is an example layout diagram illustrating an R area of FIG. 1. FIG. 3 is a cross-sectional view taken along lines A1-A1 and A2-A2 of FIG. 2. FIG. 4 is a cross-sectional view taken along a line B-B of FIG. 2. FIG. 5 is a partial layout diagram illustrating a semiconductor memory device according to some embodiments.

Referring to FIG. 1 to FIG. 5, a semiconductor memory device according to some embodiments includes a substrate 100, an element isolation pattern 105, a word-line structure 110, a base insulating film 120, a direct contact DC, a bit-line structure BLS, a buried contact BC, a fence insulating film 170, an edge insulating film 175, a landing pad LP, an isolation insulating film 180, a capacitor structure 190, and a contact plug CP.

The substrate 100 may be a semiconductor substrate, such as a silicon wafer. The substrate 100 may have a structure in which a base substrate and an epi layer are stacked. However, embodiments of the present disclosure are not limited thereto. The substrate 100 may be a silicon substrate, a gallium arsenide substrate, a silicon germanium substrate, or an SOI (Semiconductor On Insulator) substrate. An example in which the substrate 100 is embodied as a silicon substrate is described below.

The substrate 100 may include a cell area CR and a peripheral area PR. The cell area CR may be a memory cell array area where memory cells are disposed. The peripheral area PR may be a core/peri area formed around the cell area CR. Peripheral circuit elements may be formed on the peripheral area PR to control functions of the memory cells formed on the cell area CR. It is illustrated only that the peripheral area PR surrounds the cell area CR in a horizontal plane (e.g., an XY plane including a first direction Y and a second direction X that intersect each other). However, this is only an example, and the cell area CR and the peripheral area PR may be positioned in various other forms.

The cell area CR may include a first area I and the second area II. The first area I and the second area II may be arranged along the first direction Y. The second area II may be interposed between the first area I and the peripheral area PR in the first direction Y. The second area II may be a boundary area disposed at an edge of the cell area CR.

The cell area CR of the substrate 100 may include an active pattern AP. The active pattern AP may be defined by the element isolation pattern 105 within the cell area CR. The element isolation pattern 105 may include an insulating material, for example, at least one of silicon oxide, silicon nitride, silicon oxynitride, silicon oxycarbonitride, and a combination thereof. However, embodiments of the present disclosure are not limited thereto. The element isolation pattern 105 may be embodied as a single film made of one type of an insulating material, or may be embodied as a stack of multiple films respectively made of several types of insulating materials.

The active patterns AP may have a plurality of bar shapes extending in parallel to each other. In some embodiments, a center of one of the plurality of active patterns AP may be disposed adjacent to an end of another active pattern AP of the plurality of active patterns AP. In some embodiments, the active pattern AP may be formed in a diagonal bar shape. For example, as illustrated in FIG. 2, the active pattern AP may have a bar shape extending in a third direction W different from the second direction X and the first direction Y, in a plane extending in the first direction Y and the second direction X.

The active pattern AP may include a first portion (e.g., a center portion) and a second portion (e.g., an end portion). Each of the first portion and the second portion may contain an impurity and be provided as a source/drain area. In some embodiments, the first portion (e.g., the center portion) may be connected to the bit-line structure BLS via the direct contact DC, and the second portion (e.g., the end portion) may be connected to the capacitor structure 190 via the buried contact BC and/or the landing pad LP.

The word-line structure 110 may be formed on the cell area CR of the substrate 100. The word-line structure 110 may extend in an elongate manner in the second direction X parallel to an upper surface of the substrate 100. For example, the word-line structure 110 may extend cross the active pattern AP obliquely and extend cross the bit-line structure BLS in a perpendicular manner thereto. A plurality of word-line structures 110 may be spaced apart from each other in the first direction Y and may extend in the second direction X in a parallel manner to each other and may be arranged side by side. In some embodiments, the plurality of word-line structures 110 may be equally spaced from each other.

The word-line structure 110 may cross the active pattern AP between the direct contact DC and the buried contact BC. For example, the word-line structure 110 may cross the active pattern AP between the first portion (e.g., the center portion of the active pattern AP) and the second portion (e.g., the end portion of the active pattern AP).

In some embodiments, two word-line structures 110 may cross one active pattern AP. For example, the two word-line structures 110 may be respectively disposed on both opposing sides of the direct contact DC. These two word-line structures 110 may share one direct contact DC.

As illustrated in FIG. 4, the word-line structure 110 may include a gate dielectric film 112, a gate electrode 114, and a gate capping film 116. The gate dielectric film 112, the gate electrode 114, and the gate capping film 116 may be sequentially stacked on the substrate 100.

The gate dielectric film 112 may be interposed between the active pattern AP and the gate electrode 114. The gate dielectric film 112 may be interposed between the element isolation pattern 105 and the gate electrode 114. The gate dielectric film 112 may include, but is not limited to, at least one of silicon oxide, silicon oxynitride, silicon nitride, and a high-k material having a dielectric constant higher than that of silicon oxide.

The gate electrode 114 may be formed on the gate dielectric film 112. The gate electrode 114 may extend in the second direction X. The gate electrode 114 may be embodied as a single film, or may be embodied as a stack of multi-films as illustrated. For example, the gate electrode 114 may include a first electrode film 114a and a second electrode film 114b that are sequentially stacked on the gate dielectric film 112. Each of the first electrode film 114a and the second electrode film 114b may include a conductive material, for example, at least one of polysilicon, TiN, TiSiN, tungsten, tungsten silicide, and a combination thereof. However, embodiments of the present disclosure are not limited thereto.

The gate electrode 114 may be provided as a word-line of the semiconductor memory device. Each of the first portion (e.g., the center portion) and the second portion (e.g., the end portion) of the active pattern AP may be provided as a source/drain area of a field effect transistor using the gate electrode 114 as a gate electrode. An area of the active pattern AP between the first portion and the second portion may be provided as a channel area of the field effect transistor.

The gate capping film 116 may extend along an upper surface of the gate electrode 114. The gate capping film 116 may include an insulating material, for example, at least one of silicon oxide, silicon nitride, silicon oxynitride, silicon oxycarbonitride, and a combination thereof. However, embodiments of the present disclosure are not limited thereto. The gate capping film 116 may be embodied as a single film or a stack of multi-films respectively made of various types of insulating materials.

In some embodiments, the word-line structure 110 may be embedded in the substrate 100. For example, a gate trench WLt extending in the second direction X may be formed within the active pattern AP and the element isolation pattern 105. The gate dielectric film 112 may extend along a profile of the gate trench WLt. The gate electrode 114 may fill a portion of the gate trench WLt while being disposed on the gate dielectric film 112. The gate capping film 116 may fill another portion of the gate trench WLt while being disposed on the gate dielectric film 112 and the gate electrode 114. In this case, a vertical level of an upper surface of the gate electrode 114 may be lower than a vertical level of each of an upper surface of the active pattern AP and an upper surface of the element isolation pattern 105.

In some embodiments, some of the plurality of word-line structures 110 may be disposed on the second area II. The word-line structure 110 disposed on the second area II may be provided as a dummy word-line D110 that does not constitute a memory cell. The dummy word-line D110 may be used to improve uniformity of a pattern in a patterning process for forming the word-line structure 110.

The base insulating film 120 may be formed on the substrate 100. The base insulating film 120 may extend along the upper surface of the active pattern AP, the upper surface of the element isolation pattern 105, and an upper surface of the word-line structure 110. The base insulating film 120 may be embodied as a single film, or may be embodied as a stack of multi-films as illustrated in FIG. 3. For example, the base insulating film 120 may include a first insulating film 122, a second insulating film 124, and a third insulating film 126 that are sequentially stacked on the active pattern AP and the element isolation pattern 105. The second insulating film 124 may include a material having a different etching selectivity from that of the first insulating film 122. For example, the first insulating film 122 may include a silicon oxide film, and the second insulating film 124 may include a silicon nitride film. The third insulating film 126 may include a material having a lower dielectric constant than that of the second insulating film 124. For example, the second insulating film 124 may include a silicon nitride film, and the third insulating film 126 may include a silicon oxide film.

The direct contact DC may be connected to the active pattern AP. The direct contact DC may connect the active pattern AP and the bit-line structure BLS to each other. For example, a first contact trench CT1 may be formed in the substrate 100 and extend through the base insulating film 120 to expose the first portion (e.g., the center portion) of the active pattern AP. The direct contact DC may be formed in the first contact trench CT1 to electrically connect the first portion of the active pattern AP and the conductive pattern 130 to each other.

The bit-line structure BLS may be formed on the cell area CR of the substrate 100. The bit-line structure BLS may extend in an elongate manner in the first direction Y parallel to the upper surface of the substrate 100. For example, the bit-line structure BLS may extend cross the active pattern AP obliquely and cross the word-line structure 110 in a perpendicular manner thereto. A plurality of bit-line structures BLS may be spaced apart from each other in the second direction X and extend in parallel to each other and in the first direction Y and may be arranged side by side. In some embodiments, the plurality of bit-line structures BLS may be spaced apart from each other by an equal spacing.

As shown in FIG. 3, the bit-line structure BLS may include a conductive pattern 130, a capping pattern 135, and a spacer structure 140.

The conductive pattern 130 may be formed on the substrate 100. The conductive pattern 130 may extend in an elongate manner in the first direction Y and along an upper surface of the base insulating film 120. The conductive pattern 130 may be embodied as a single film, or may be embodied as a stack of multi-films, as shown in FIG. 3. For example, the conductive pattern 130 may include a first conductive film 131, a second conductive film 132, and a third conductive film 133 that are sequentially stacked on the base insulating film 120. Each of the first conductive film 131, the second conductive film 132, and the third conductive film 133 may include a conductive material, for example, at least one of polysilicon, TiN, TiSiN, tungsten, tungsten silicide, and a combination thereof. However, embodiments of the present disclosure are not limited thereto. For example, the first conductive film 131 may include a polysilicon (poly-Si) film, the second conductive film 132 may include a TiSiN film, and the third conductive film 133 may include a tungsten (W) film. The conductive pattern 130 may be provided as a bit-line of the semiconductor memory device.

The conductive pattern 130 may have an end portion on the second area II. For example, as illustrated in FIG. 5, the conductive pattern 130 may include line portions L1 and L2 and edge portions E1 and E2. The line portions L1 and L2 may extend in an elongate manner in the first direction Y while being disposed on the first area I. The edge portions E1 and E2 may respectively extend further from the line portions L1 and L2 toward the peripheral area PR. The edge portions E1 and E2 may have an end of the conductive pattern 130 while being disposed on the second area II. For example, the edge portions E1 and E2 may be spaced apart from the peripheral area PR.

The conductive pattern 130 may extend in the first direction Y over the first area I and the second area II, and the end of the conductive pattern 130 formed on the second area II may be spaced apart from the peripheral area PR.

The capping pattern 135 may extend along an upper surface of the conductive pattern 130. The capping pattern 135 may be embodied as a single film, or may be embodied as a stack of multi-films as shown in FIG. 3. For example, the capping pattern 135 may include a first capping film 136, a second capping film 137, and a third capping film 138 that are sequentially stacked on the conductive pattern 130. The first capping film 136, the second capping film 137, and the third capping film 138 may include an insulating material, for example, at least one of silicon oxide, silicon nitride, silicon oxynitride, silicon carbonitride, and a combination thereof. However, embodiments of the present disclosure are not limited thereto. For example, each of the first capping film 136, the second capping film 137, and the third capping film 138 may include a silicon nitride film.

The spacer structure 140 may extend along a side surface of the conductive pattern 130 and a side surface of the capping pattern 135. The spacer structure 140 may include an insulating material, for example, at least one of silicon oxide, silicon nitride, silicon oxynitride, silicon carbonitride, and a combination thereof. However, embodiments of the present disclosure are not limited thereto.

In some embodiments, the spacer structure 140 may be embodied as a stack of multiple films respectively made of various types of insulating materials. For example, the spacer structure 140 may include a base spacer 141, a first lower spacer 142, a second lower spacer 143, a first side spacer 144, and a second side spacer 145.

The base spacer 141 may extend along the side surface of the conductive pattern 130, a side surface of the direct contact DC, and the side surface of the capping pattern 135.

In some embodiments, the base spacer 141 may be the innermost spacer of the spacer structure 140 that contacts the conductive pattern 130, the direct contact DC, and the capping pattern 135.

In some embodiments, the base spacer 141 may further extend along the upper surface of the base insulating film 120. In some embodiments, the base spacer 141 may extend along the first contact trench CT1.

The first lower spacer 142 may be formed on the base spacer 141 and within the first contact trench CT1. For example, the first lower spacer 142 may extend conformally along a profile of the base spacer 141 and within the first contact trench CT1.

The second lower spacer 143 may be formed on the first lower spacer 142 and within the first contact trench CT1. For example, the second lower spacer 143 may fill an area of the first contact trench CT1 that remains after the base spacer 141 and the first lower spacer 142 have been formed therein.

The first side spacer 144 may be formed on an outer side surface of the base spacer 141. Furthermore, the first side spacer 144 may be formed on an upper surface of the first lower spacer 142 and an upper surface of the second lower spacer 143.

The second side spacer 145 may be formed on an outer side surface of the first side spacer 144. Furthermore, the second side spacer 145 may be formed on the upper surface of the second lower spacer 143. In some embodiments, the second side spacer 145 may be the outermost spacer of the spacer structure 140 that contacts the buried contact BC and/or the landing pad LP.

In some embodiments, the second side spacer 145 may further extend along the side surface of the base insulating film 120, the upper surface of the active pattern AP, the upper surface of the element isolation pattern 105, and the upper surface of the word-line structure 110. In some embodiments, a vertical level of the lowermost surface of the second side spacer 145 may be lower than that of the uppermost surface of the second lower spacer 143.

Each of the base spacer 141, the first lower spacer 142, the second lower spacer 143, the first side spacer 144, and the second side spacer 145 may include an insulating material, for example, at least one of silicon oxide, silicon nitride, silicon oxynitride, silicon oxycarbonitride, and combinations thereof. However, embodiments of the present disclosure are not limited thereto.

In some embodiments, the first lower spacer 142 may include a material having a lower dielectric constant than that of the base spacer 141 and/or the second lower spacer 143. For example, the first lower spacer 142 may include a silicon oxide film, and each of the base spacer 141 and the second lower spacer 143 may include a silicon nitride film.

In some embodiments, the first side spacer 144 may include a material having a lower dielectric constant than that of the base spacer 141 and/or the second side spacer 145. For example, the first side spacer 144 may include a silicon oxide film, and each of the base spacer 141 and the second side spacer 145 may include a silicon nitride film.

The buried contact BC may be formed on the first area I of the substrate 100. The buried contact BC may not be formed on the second area II of the substrate 100. The buried contact BC may be connected to the active pattern AP. For example, a second contact trench CT2 may be formed in the first area I of the substrate 100 and extend through the base insulating film 120 to expose the second portion (e.g., an end portion) of the active pattern AP. The buried contact BC may be formed in the second contact trench CT2 to be electrically connected to the second portion of the active pattern AP.

The buried contact BC may be formed on a side surface of the bit-line structure BLS. Furthermore, the buried contact BC may be spaced from the conductive pattern 130 by the spacer structure 140. For example, as illustrated in FIG. 3, the buried contact BC may extend along a portion of an outer side surface of the spacer structure 140.

The buried contact BC may include a conductive material, for example, at least one of polysilicon, TiN, TiSiN, tungsten, tungsten silicide, and combinations thereof. However, embodiments of the present disclosure are not limited thereto. For example, the buried contact BC may include a conductive semiconductor material, such as polysilicon (poly-Si) doped with impurities.

In some embodiments, the buried contact BC may include a first filling conductive film 152 and a silicide film 154.

The first filling conductive film 152 may fill the second contact trench CT2. The first filling conductive film 152 may extend along a portion of the side surface of the bit-line structure BLS. The first filling conductive film 152 may include a conductive semiconductor material, for example, polysilicon (poly-Si) doped with impurities.

The silicide film 154 may be interposed between the first filling conductive film 152 and the landing pad LP. The silicide film 154 may be formed based on a reaction between a semiconductor element (for example, silicon (Si)) contained in the first filling conductive film 152 and a metal element (for example, a metal element included in the landing pad LP). The silicide film 154 may include, for example, a metal silicide such as nickel silicide, cobalt silicide, tungsten silicide, titanium silicide, niobium silicide, or tantalum silicide. However, embodiments of the present disclosure are not limited thereto.

The fence insulating film 170 may be formed on the first area I of the substrate 100. The fence insulating film 170 may be formed on the side surface of the bit-line structure BLS. The fence insulating film 170 may be spaced from the conductive pattern 130 by the spacer structure 140.

In some embodiments, the fence insulating film 170 may overlap the word-line structure 110 in a fourth direction Z intersecting the upper surface of the substrate 100. On the first area I of the substrate 100, the buried contacts BC and the fence insulating films 170 may be alternately arranged with each other along the first direction Y.

The fence insulating film 170 may include an insulating material, for example, at least one of silicon oxide, silicon nitride, silicon oxynitride, silicon oxycarbonitride, and a combination thereof. However, embodiments of the present disclosure are not limited thereto. For example, the fence insulating film 170 may include a silicon nitride film.

The bit-line structures BLS and the fence insulating films 170 may define a plurality of isolated areas arranged in a lattice structure. The buried contacts BC may be respectively formed within the isolated areas and spaced from each other. For example, based on the upper surface of the substrate 100, a vertical level of the upper surface of the capping pattern 135 may be higher than a vertical level of the upper surface of the buried contact BC. Adjacent ones of a plurality of buried contacts BC arranged along the second direction X may be spaced from each other via each of the plurality of bit-line structures BLS arranged along the second direction X. Furthermore, for example, based on the upper surface of the substrate 100, a vertical level of the upper surface of the fence insulating film 170 may be higher than the vertical level of the upper surface of the buried contact BC. Adjacent ones of a plurality of buried contacts BC arranged along the first direction Y may be spaced from each other via each of a plurality of fence insulating films 170 arranged along the first direction Y.

The edge insulating film 175 may be formed on the second area II of the substrate 100. The edge insulating film 175 may be formed on the side surface of the bit-line structure BLS. The edge insulating film 175 may be spaced from the conductive pattern 130 by the spacer structure 140. The edge insulating film 175 may extend along the end of the conductive pattern 130 formed on the second area II. For example, as illustrated in FIG. 5, the edge insulating film 175 may extend along the edge portions E1 and E2.

In some embodiments, the conductive pattern 130 may include a first conductive line 1301, a second conductive line 1302, a third conductive line 1303, and a fourth conductive line 1304 that are spaced apart from each other and arranged sequentially in the second direction X. The second and fourth conductive lines 1302 and 1304 may protrude in the first direction Y beyond the first and third conductive lines 1301 and 1303 toward the peripheral area PR. For example, each of the first and third conductive lines 1301 and 1303 may include the first line portion L1 and the first edge portion E1, and each of the second and fourth conductive lines 1302 and 1304 may include the second line portion L2 and the second edge portion E2. The end of the second edge portion E2 may be closer to the peripheral area PR than the end of the first edge portion E1 may be. The edge insulating film 175 may be formed on a side surface of the first edge portion E1 and a side surface of the second edge portion E2.

In some embodiments, a width of the first line portion L1 and a width of the second line portion L2 may be equal to each other. In the present disclosure, the term “equal” means not only exactly equal but also including a slight difference that may occur due to a process margins, etc. For example, a width W1 of the first line portion L1 in the second direction X and a width W2a of the second line portion L2 in the second direction X may be equal to each other.

In some embodiments, the edge insulating film 175 may include a first filling portion 175A, a second filling portion 175B, and a third filling portion 175C. Each of the first filling portion 175A and the third filling portion 175C may overlap the first edge portion E1 in the second direction X. The first edge portion E1 may be interposed between the first filling portion 175A and the second filling portion 175B in the second direction X. The third filling portion 175C may overlap the first edge portion E1 in the first direction Y and may overlap the second edge portion E2 in the second direction X. The third filling portion 175C may be connected to the first filling portion 175A and the second filling portion 175B to constitute an integral edge insulating film 175. That is, the first filling portion 175A, the second filling portion 175B, and the third filling portion 175C may be extended continuously without being separated by other components to form an approximately “Y”shaped structure in the view of plane.

In some embodiments, a portion of the spacer structure 140 may be interposed between the edge insulating film 175 and the peripheral area PR. For example, a filling insulating film 210 may be formed on the peripheral area PR. A portion of the spacer structure 140 may further extend in the second direction X and along the filling insulating film 210 and may be interposed between the edge insulating film 175 and the filling insulating film 210.

In some embodiments, a portion of the second side spacer 145 may be interposed between the substrate 100 and the edge insulating film 175. For example, as illustrated in FIG. 3 and FIG. 4, the second side spacer 145 may extend further along the upper surface of the active pattern AP of the second area II, the upper surface of the element isolation pattern 105 of the second area II, and the upper surface of the word-line structure 110 of the second area II. The edge insulating film 175 may extend along an outer side surface and an upper surface of the second side spacer 145.

The edge insulating film 175 is illustrated as only contacting the buried contact BC in the first direction Y. However, this is only example, and the edge insulating film 175 may contact the fence insulating film 170 in the first direction Y. For example, unlike what is illustrated, the fence insulating film 170 may be interposed between the buried contact BC and the edge insulating film 175.

The landing pad LP may be formed on the first area I and the second area II. The landing pad LP may be formed on the upper surface of the buried contact BC, the upper surface of the fence insulating film 170, and the upper surface of the edge insulating film 175. The landing pad LP may electrically contact the buried contact BC. The landing pad LP may define a plurality of isolated areas that are spaced apart from each other. For example, a pad trench LPt defining each of a plurality of landing pads LP that are spaced apart from each other may be formed.

The landing pad LP may include a conductive material, for example, at least one of polysilicon, TiN, TiSiN, tungsten, tungsten silicide, and a combination thereof. However, embodiments of the present disclosure are not limited thereto. For example, the landing pad LP may include tungsten (W).

In some embodiments, the landing pad LP on the first area I may be formed across the bit-line structure BLS and the buried contact BC. For example, one portion of the landing pad LP may overlap the buried contact BC in the fourth direction Z, and the other portion of the landing pad LP may overlap the capping pattern 135 and the spacer structure 140 in the fourth direction Z. A vertical level of a lower surface of the pad trench LPt on the first area I may be lower than a vertical level of an upper surface of the capping pattern 135 and may be higher than a vertical level of an upper surface of the conductive pattern 130. In some embodiments, a portion of the pad trench LPt may overlap the capping pattern 135 and the spacer structure 140 in the fourth direction Z. Accordingly, the pad trench LPt on the first area I may define each of the plurality of landing pads LPs spaced apart from each other on the first area I.

In some embodiments, the landing pad LP on the second area II may be formed on the edge insulating film 175. For example, the landing pad LP may extend along the upper surface of the edge insulating film 175. A vertical level of the lower surface of the pad trench LPt on the second area II may be lower than a vertical level of the upper surface of the edge insulating film 175. Accordingly, the pad trench LPt on the second area II may define each of the plurality of landing pads LPs spaced apart from each other on the second area II.

In some embodiments, the landing pad LP on the second area II may be provided as a dummy landing pad DLP that does not constitute a memory cell. The dummy landing pad DLP may be used to improve uniformity of a pattern in a patterning process for forming the landing pad LP.

In some embodiments, the plurality of landing pads LP may be arranged in a honeycomb structure. The landing pads LP arranged in the honeycomb structure may further improve an integration level of the semiconductor memory device.

In some embodiments, the landing pad LP may include a lower pad 156 and an upper pad 158.

The lower pad 156 may be formed on the first area I. The lower pad 156 may not be formed on the second area II. The lower pad 156 may be formed on the upper surface of the buried contact BC and the side surface of the bit-line structure BLS. For example, the lower pad 156 may fill a space on the upper surface of the buried contact BC and the side surface of the bit-line structure BLS. A vertical level of the uppermost surface of the lower pad 156 may be equal to or lower than that of the uppermost surface of the capping pattern 135. In some embodiments, the vertical level of the uppermost surface of the lower pad 156 may be equal to the vertical level of the uppermost surface of the capping pattern 135 based on the upper surface of the substrate 100. Adjacent ones of the plurality of lower pads 156 arranged along the second direction X may be spaced from each other via each of the plurality of bit-line structures BLS arranged along the second direction X.

In some embodiments, the lower pad 156 may include a barrier conductive film 156a and a second filling conductive film 156b.

The barrier conductive film 156a may conformally extend along a profile of a combination of the upper surface of the buried contact BC and the side surface of the spacer structure 140. In some embodiments, a vertical level of the uppermost surface of the barrier conductive film 156a may be equal to a vertical level of the uppermost surface of the bit-line structure BLS. The barrier conductive film 156a may include a metal or a metal nitride to prevent diffusion of a metal element contained in the second filling conductive film 156b. For example, the barrier conductive film 156a may include at least one of titanium (Ti), tantalum (Ta), tungsten (W), nickel (Ni), cobalt (Co), platinum (Pt), alloys thereof, and nitrides thereof. However, embodiments of the present disclosure are not limited thereto. In one example, the barrier conductive film 156a may include a titanium nitride (TiN) film.

The second filling conductive film 156b may be formed on the barrier conductive film 156a. The second filling conductive film 156b may fill a space on the upper surface of the buried contact BC and the side surface of the bit-line structure BLS. The second filling conductive film 156b may include a conductive metal, for example, tungsten (W).

The upper pad 158 may be formed on the first area I and the second area II. The upper pad 158 may be formed in each of the plurality of isolated areas that are spaced from each other via the pad trench LPt. The upper pad 158 on the first area I may extend along the upper surface of the lower pad 156, the upper surface of the bit-line structure BLS, and the upper surface of the fence insulating film 170. In some embodiments, the upper pad 158 on the first area I may be in contact with the upper surface of the barrier conductive film 156a and the upper surface of the second filling conductive film 156b. The upper pad 158 on the second area II may extend along the upper surface of the bit-line structure BLS and the upper surface of the edge insulating film 175.

The upper pad 158 may include a conductive material, for example, at least one of polysilicon, TiN, TiSiN, tungsten, tungsten silicide, and combinations thereof. However, embodiments of the present disclosure are not limited thereto. In some embodiments, the upper pad 158 may include the same conductive metal as that of the second filling conductive film 156b. For example, the upper pad 158 may include tungsten (W).

Although it is illustrated that a boundary is defined between the lower pad 156 and the upper pad 158, this is only an example. Depending on a process of forming the lower pad 156 and the upper pad 158, the boundary may not be defined between the lower pad 156 and the upper pad 158.

The isolation insulating film 180 may be formed on the landing pad LP. The isolation insulating film 180 may fill the pad trench LPt. The plurality of landing pads LP may be spaced from each other via the isolation insulating film 180 and thus may correspond to the plurality of isolated areas, respectively. The isolation insulating film 180 may include, but is not limited to, at least one of silicon oxide, silicon oxynitride, silicon nitride, and a low-k material having a dielectric constant lower than that of silicon oxide.

The capacitor structure 190 may be formed on the isolation insulating film 180 and the landing pad LP. The capacitor structure 190 may electrically contact the landing pad LP. For example, the isolation insulating film 180 may be patterned to expose at least a portion of the upper surface of the landing pad LP. The capacitor structure 190 may extend through the isolation insulating film 180 to be connected to at least a portion of the upper surface of the landing pad LP.

The capacitor structure 190 may store data in each memory cell formed on the cell area CR by being controlled by the conductive pattern 130 provided as the bit-line and the gate electrode 114 provided as the word-line. In some embodiments, the capacitor structure 190 may include a lower electrode 192, a capacitor dielectric film 194, and an upper electrode 196 sequentially stacked on the landing pad LP. The capacitor structure 190 may store charge in the capacitor dielectric film 194 based on a potential difference between potentials of the lower electrode 192 and the upper electrode 196.

Each of the lower electrode 192 and the upper electrode 196 may include, for example, doped polysilicon, metal, or metal nitride. However, embodiments of the present disclosure are not limited thereto. Furthermore, the capacitor dielectric film 194 may include, for example, silicon oxide or a high-k material. However, embodiments of the present disclosure are not limited thereto.

A contact plug CP may be formed on the second area II of the substrate 100. The contact plug CP may electrically contact the conductive pattern 130. Some peripheral circuit elements (e.g., a sense amplifier) formed on the peripheral area PR may be connected to the conductive pattern 130 via the contact plug CP and may control the memory cells formed on the cell area CR. For example, as illustrated in FIG. 5, the contact plug CP may be electrically connected to the second conductive line 1302 and/or the fourth conductive line 1304 by contacting the second edge portion E2. Although not specifically illustrated, the contact plug CP may be electrically connected to the first conductive line 1301 and/or the third conductive line 1303. For example, the contact plug CP may be disposed on a boundary area opposite to the second area II around the first area I and may be electrically connected to the first conductive line 1301 and/or the third conductive line 1303.

In some embodiments, the second edge portion E2 may include an extension portion E2a and an expansion portion E2b. The extension portion E2a may overlap the first edge portion E1, the first filling portion 175A, and the second filling portion 175B in the second direction X. The expansion portion E2b may further extend from the extension portion E2a toward the peripheral area PR. The expansion portion E2b may overlap the third filling portion 175C in the second direction X. A width W2b of the expansion portion E2b in the second direction X may be larger than a width W2a of the extension portion E2a in the second direction X. The expansion portion E2b may more easily contact the contact plug CP.

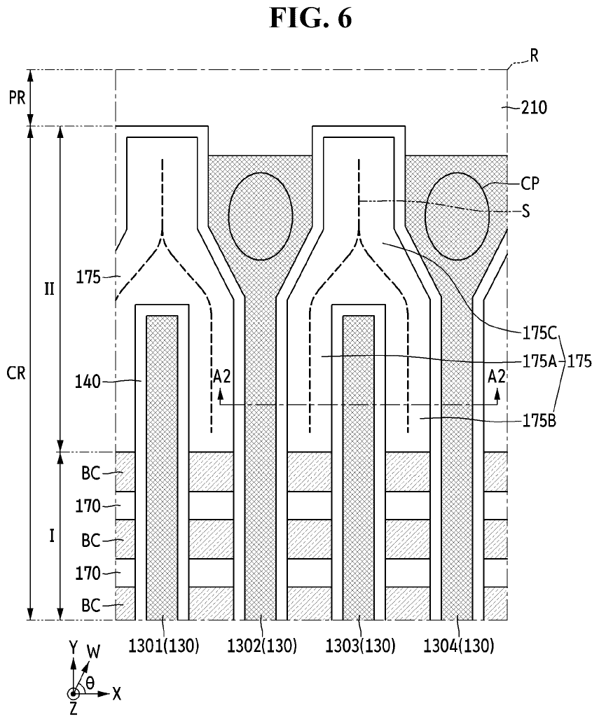

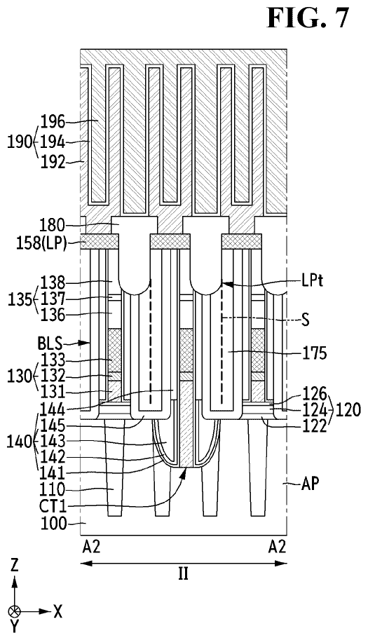

FIG. 6 is a partial layout diagram illustrating a semiconductor memory device according to some embodiments. FIG. 7 is a cross-sectional view taken along a line A2-A2 of FIG. 6. For convenience of description, contents duplicate with those as described above using FIG. 1 to FIG. 5 are briefly described or descriptions thereof are omitted.

Referring to FIG. 1, FIG. 6, and FIG. 7, in the semiconductor memory device according to some embodiments, the edge insulating film 175 includes a seam.

The seam S may be spaced from the spacer structure 140. The seam S may be a boundary of the edge insulating film 175 formed between conductive patterns 130 adjacent to each other in the second direction X. For example, the seam S may be a boundary surface at which a portion of the edge insulating film 175 stacked on the side surface of the first conductive line 1301 and another portion of the edge insulating film 175 stacked on the side surface of the second conductive line 1302 meet each other. Alternatively, for example, the seam S may be a boundary surface at which a portion of the edge insulating film 175 stacked on the side surface of the second conductive line 1302 and another portion of the edge insulating film 175 formed on the side surface of the fourth conductive line 1304 meet each other.

At least a portion of the seam S may extend in the first direction Y and may be positioned within the edge insulating film 175. For example, each of the seam S within the first filling portion 175A, the seam S within the second filling portion 175B, and the seam S within the third filling portion 175C may extend in an elongate manner in the first direction Y. In some embodiments, the seam S within the first filling portion 175A may be connected to the seam S within the third filling portion 175C. The seam S within the second filling portion 175B may be connected to the seam S within the third filling portion 175C.

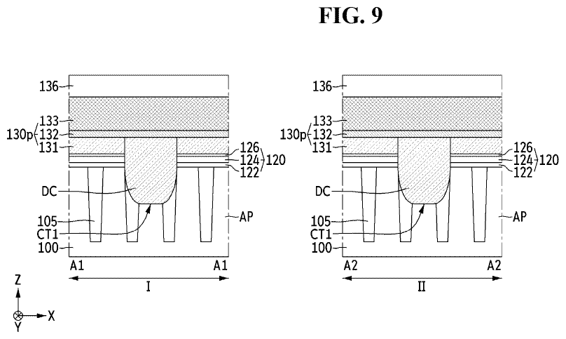

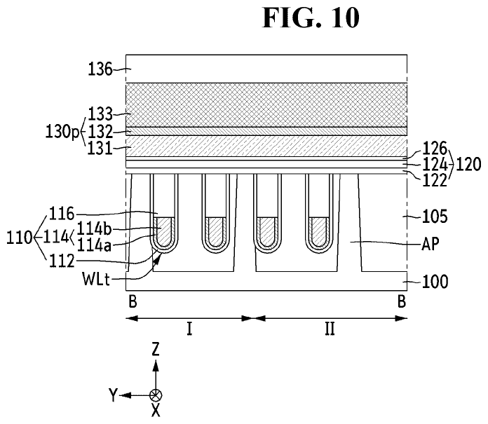

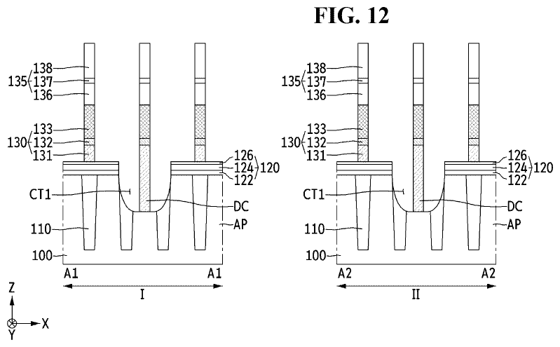

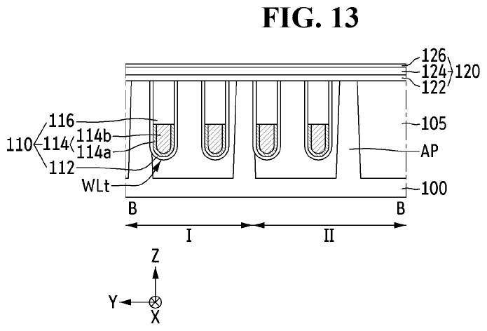

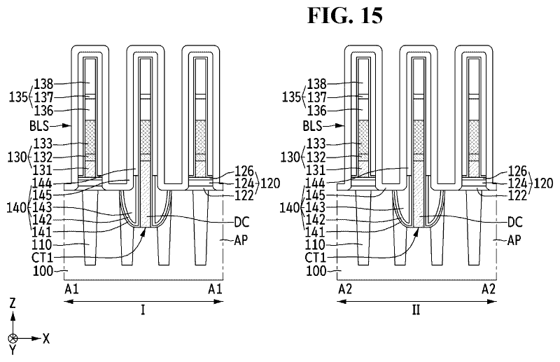

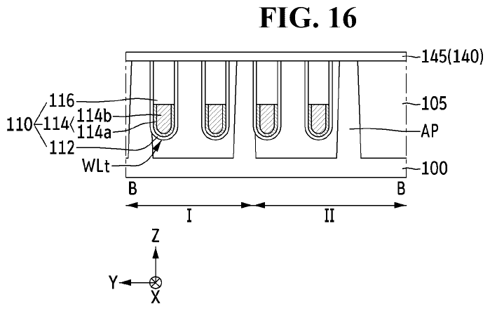

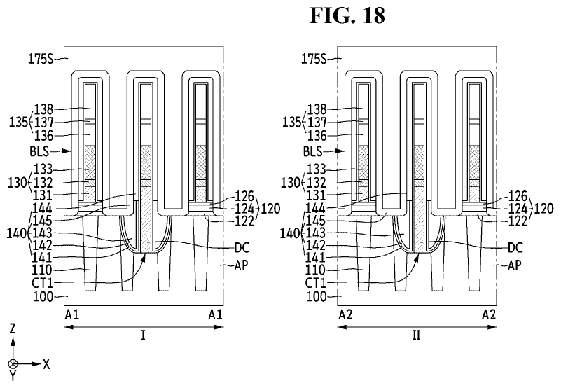

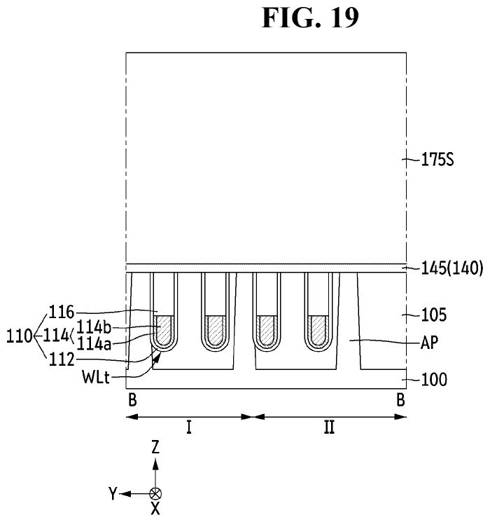

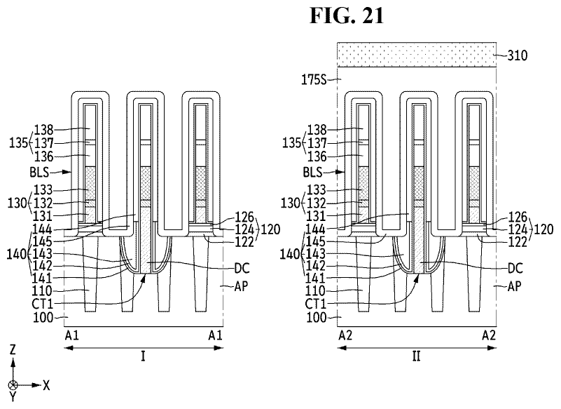

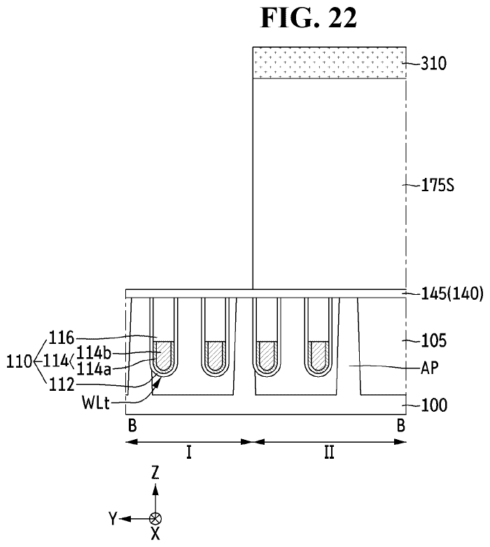

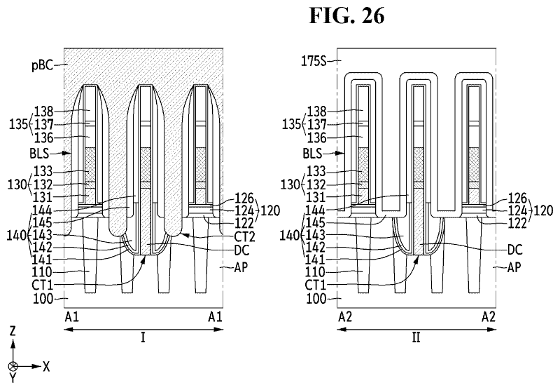

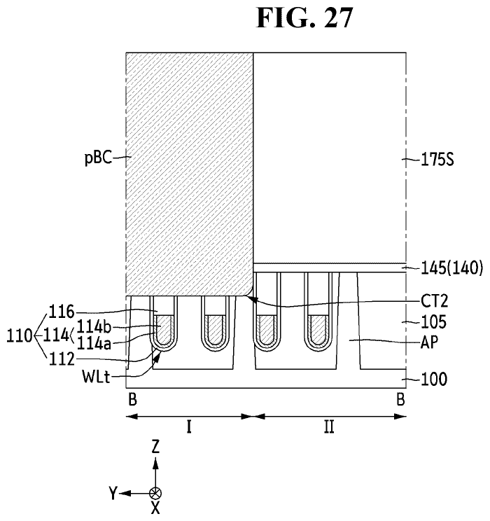

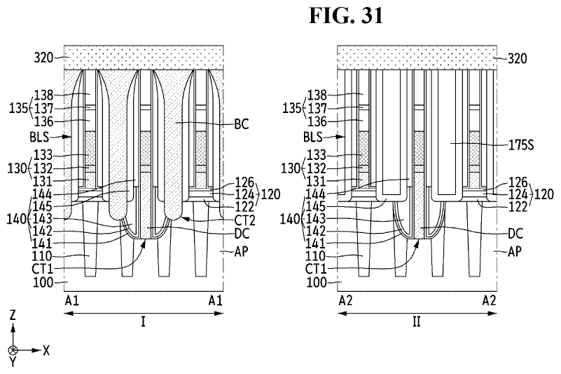

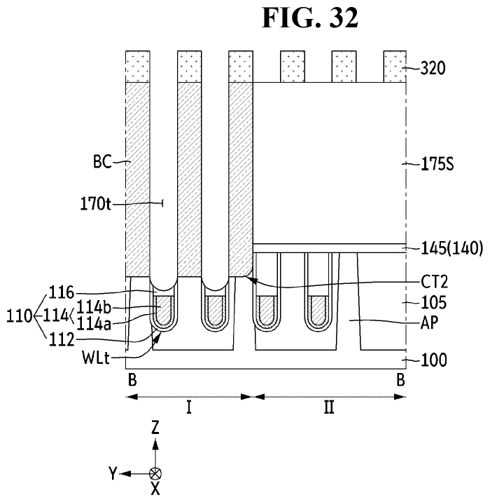

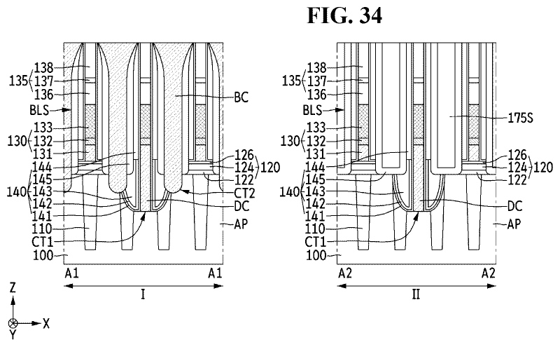

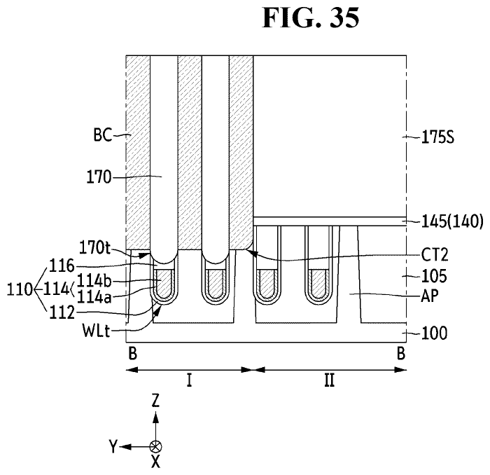

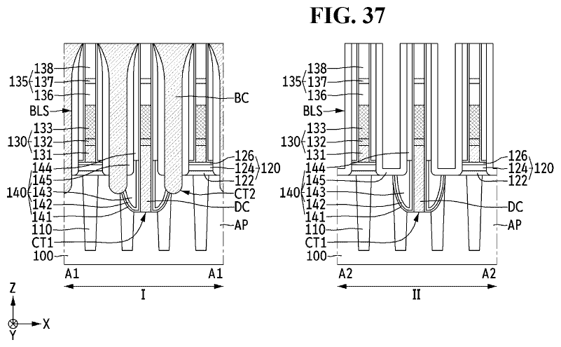

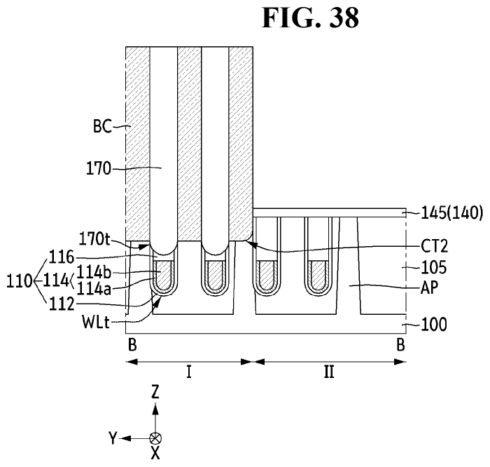

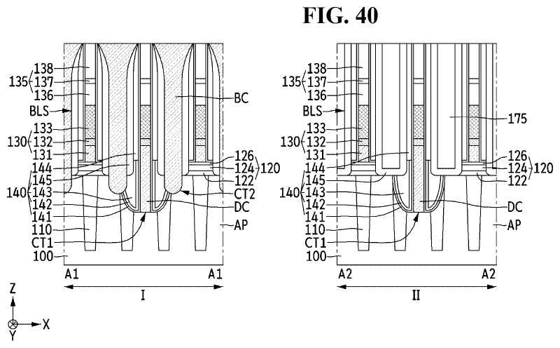

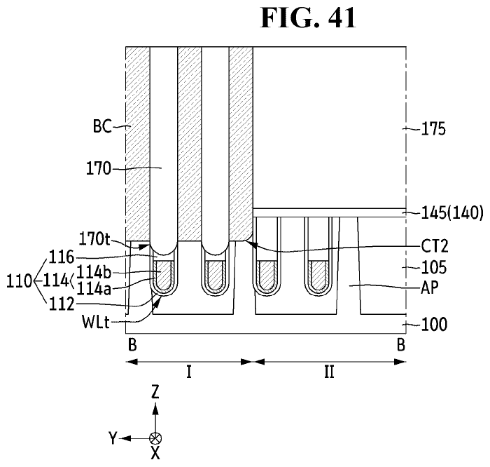

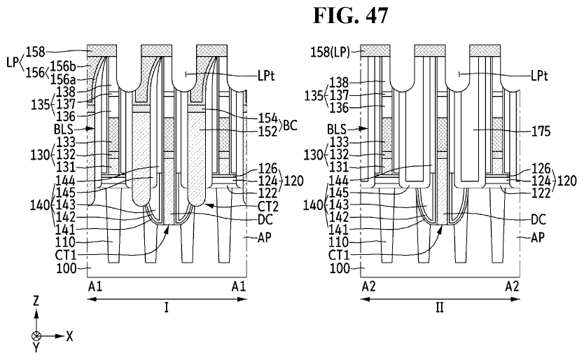

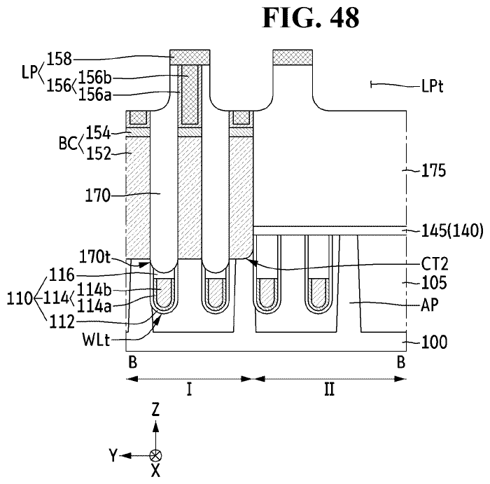

Hereinafter, with reference to FIG. 1 to FIG. 48, a method for manufacturing a semiconductor memory device according to some embodiments is described. For convenience of description, contents duplicate with those as described above using FIG. 1 to FIG. 7 are briefly described or descriptions thereof are omitted.

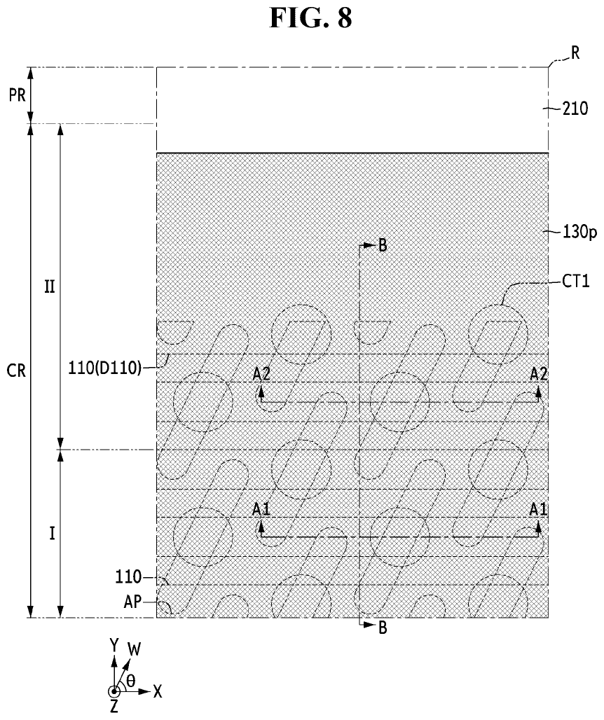

FIG. 8 to FIG. 48 are diagrams of intermediate structures corresponding to intermediate steps of a method for manufacturing a semiconductor memory device according to some embodiments.

Referring to FIG. 8 to FIG. 10, the element isolation pattern 105, the word-line structure 110, the base insulating film 120, a pre-conductive pattern 130p, the direct contact DC, and the first capping film 136 are formed on the substrate 100.

The element isolation pattern 105 may be formed within the substrate 100. The element isolation pattern 105 may define an active pattern AP within the substrate 100.

The word-line structure 110 may be formed on the cell area CR of the substrate 100. The word-line structure 110 may extend in the second direction X. In some embodiments, the word-line structure 110 may be embedded in the substrate 100.

The base insulating film 120 may be formed on the substrate 100. The base insulating film 120 may extend along the upper surface of the active pattern AP, the upper surface of the element isolation pattern 105, and the upper surface of the word-line structure 110.

The pre-conductive pattern 130p may be formed on the cell area CR. The pre-conductive pattern 130p may cover the upper surface of the base insulating film 120. In some embodiments, the pre-conductive pattern 130p may include the first conductive film 131, the second conductive film 132, and the third conductive film 133 that are sequentially stacked on the base insulating film 120.

The direct contact DC may electrically connect the active pattern AP and the pre-conductive pattern 130p to each other. For example, after the first conductive film 131 is formed on the base insulating film 120, the first contact trench CT1 exposing the first portion (e.g., the center portion) of the active pattern AP may be formed. The direct contact DC may fill the first contact trench CT1. After the direct contact DC is formed, the second conductive film 132 and the third conductive film 133 may be sequentially stacked on the first conductive film 131 and the direct contact DC.

The first capping film 136 may extend along an upper surface of the pre-conductive pattern 130p.

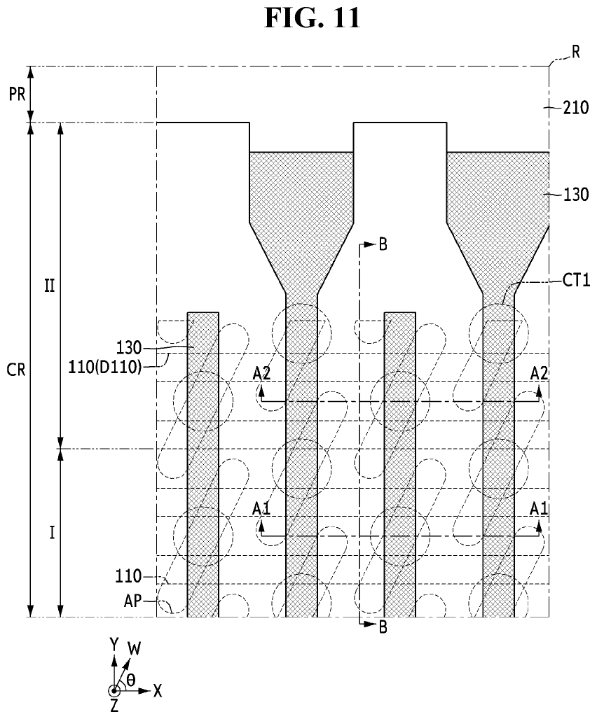

Referring to FIG. 11 to FIG. 13, the conductive pattern 130 and the capping pattern 135 are formed.

For example, the second capping film 137 and the third capping film 138 may be sequentially formed on the first capping film 136. Subsequently, a patterning process may be performed on the first to third conductive films 131 to 133 and the first to third capping films 136 to 138. As the patterning process is performed, the conductive pattern 130 extending in an elongate manner in the first direction Y and the capping pattern 135 extending along the upper surface of the conductive pattern 130 may be formed.

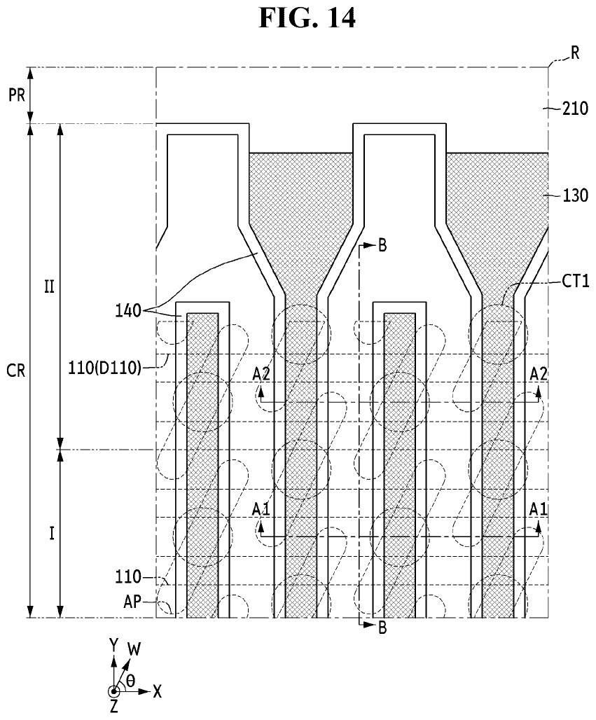

Referring to FIG. 14 to FIG. 16, the spacer structure 140 is formed.

The spacer structure 140 may extend along the side surface of the conductive pattern 130 and the side surface of the capping pattern 135. In some embodiments, the spacer structure 140 may include the base spacer 141, the first lower spacer 142, the second lower spacer 143, the first side spacer 144, and the second side spacer 145.

The base spacer 141 may extend along the side surface of the conductive pattern 130, the side surface of the direct contact DC, and the side surface of the capping pattern 135.

The first lower spacer 142 may be formed on the base spacer 141 and within the first contact trench CT1. The second lower spacer 143 may be formed on the first lower spacer 142 and within the first contact trench CT1. The first side spacer 144 may be formed on the outer side surface of the base spacer 141.

The second side spacer 145 may extend along the outer side surface of the first side spacer 144, the side surface of the base insulating film 120, the upper surface of the active pattern AP, the upper surface of the element isolation pattern 105, and the upper surface of the word-line structure 110. For example, an etching process on the base insulating film 120 may be performed using the first side spacer 144 as an etching mask. After the etching process has been performed, the second side spacer 145 may be stacked on the first side spacer 144.

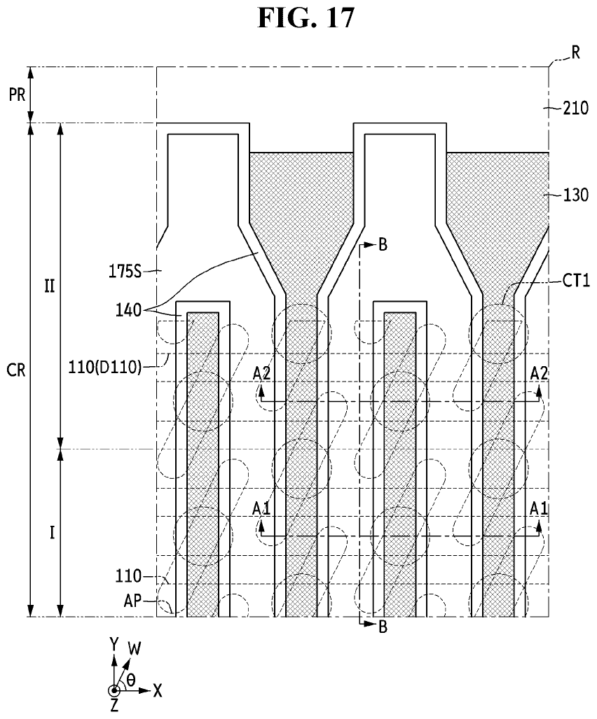

Referring to FIG. 17 to FIG. 19, a sacrificial film 175S is formed on the spacer structure 140.

The sacrificial film 175S may be formed on the first area I and the second area II. The sacrificial film 175S may cover the spacer structure 140. The sacrificial film 175S may be formed to fill a space on the side surface of the conductive pattern 130. For example, the sacrificial film 175S may fill a space on the outer side surface and the upper surface of the second side spacer 145.

The sacrificial film 175S may include a material having an etching selectivity with respect to the spacer structure 140. In one example, the second side spacer 145 may include a silicon nitride film, and the sacrificial film 175S may include a silicon oxide film.

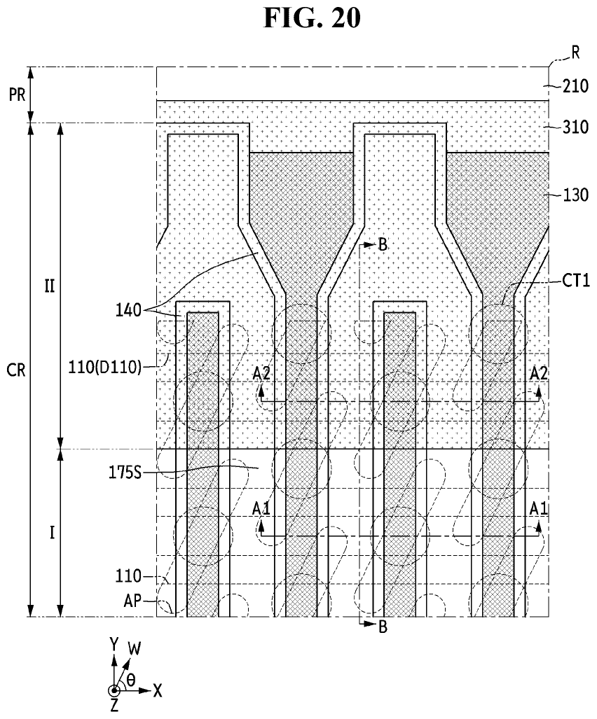

Referring to FIG. 20 to FIG. 22, a portion of the sacrificial film 175S on the first area I is removed.

For example, a first mask pattern 310 may be formed on the sacrificial film 175S. The first mask pattern 310 may cover the sacrificial layer 175S on the second area II, and may expose the sacrificial film 175S on the first area I. The first mask pattern 310 may include, for example, a photoresist pattern. However, embodiments of the present disclosure are not limited thereto.

Next, an etching process using the first mask pattern 310 as an etching mask may be performed. As the etching process is performed, the portion of the sacrificial film 175S on the first area I may be removed, and the portion of the spacer structure 140 on the first area I may be exposed.

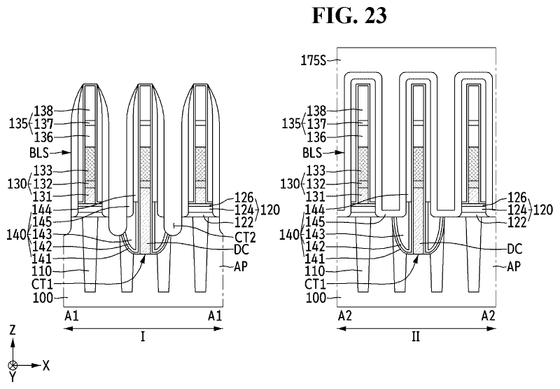

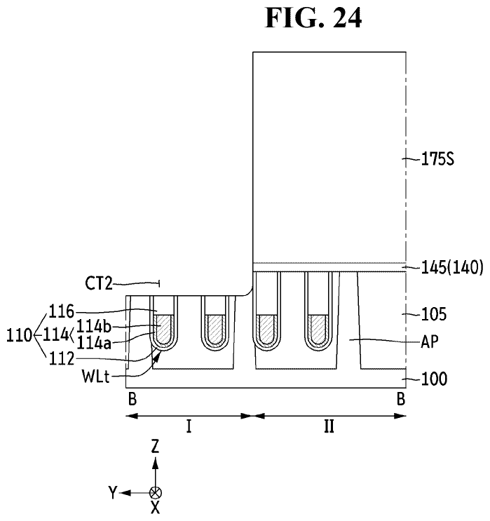

Referring to FIG. 23 and FIG. 24, the second contact trench CT2 is formed in the first area I.

The second contact trench CT2 may extend through the portion of the second side spacer 145 on the first area I to expose the second portion (e.g., the end portion) of the active pattern AP. For example, an etching process using the bit-line structure BLS as an etching mask may be performed. As the above etching process is performed, a portion of the second side spacer 145 extending along a horizontal plane (e.g., XY plane) may be removed to expose the second portion of the active pattern AP. The portion of the second side spacer 145 on the second area II may be protected with the sacrificial film 175S and thus may not be etched in the etching process.

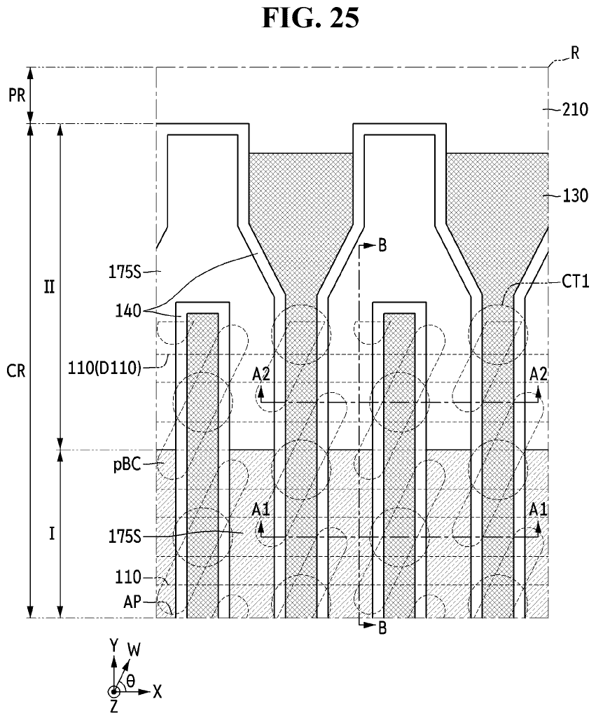

Referring to FIG. 25 to FIG. 27, a pre-contact film pBC is formed.

The pre-contact film pBC may cover a side surface and an upper surface of a portion of the bit-line structure BLS on the first area I. Furthermore, the pre-contact film pBC may fill the second contact trench CT2. Accordingly, the pre-contact film pBC may be connected to the second portion (e.g., the end portion) of the active pattern AP.

The pre-contact film pBC may include a conductive material, for example, at least one of polysilicon, TiN, TiSiN, tungsten, tungsten silicide, and combinations thereof. However, embodiments of the present disclosure are not limited thereto. For example, the pre-contact film pBC may include a conductive semiconductor material, for example, polysilicon (poly-Si) doped with impurities.

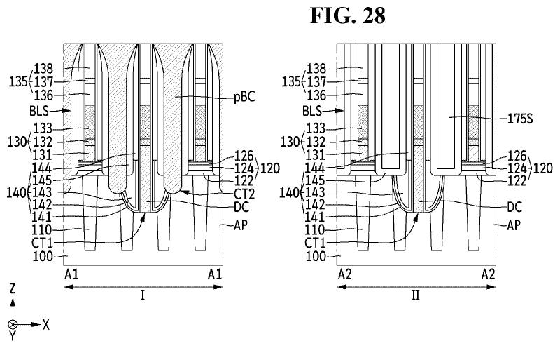

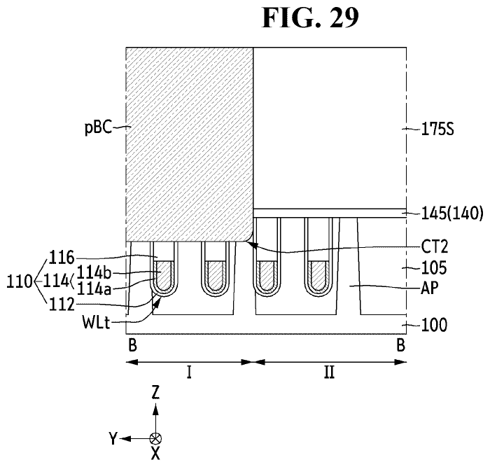

Referring to FIG. 28 and FIG. 29, a planarization process is performed.

The planarization process may include, for example, a chemical mechanical polishing (CMP) process. However, embodiments of the present disclosure are not limited thereto. As the planarization process is performed, the upper surface of the bit-line structure BLS may be exposed. For example, as the planarization process is performed, the upper surface of the bit-line structure BLS, the upper surface of the pre-contact film pBC, and the upper surface of the sacrificial film 175S may be coplanar with each other. Furthermore, as the planarization process is performed, adjacent ones of a plurality of pre-contact films pBC arranged along the second direction X may be spaced from each other via each of the plurality of bit-line structures BLS arranged along the second direction X.

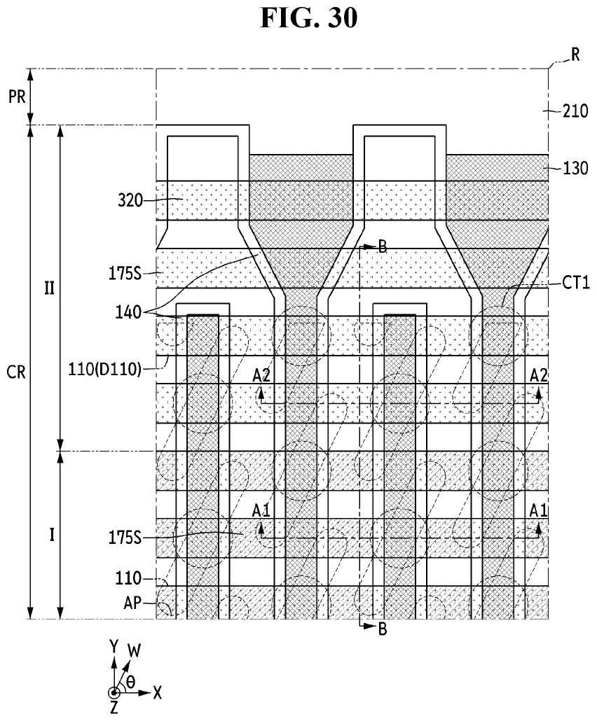

Referring to FIG. 30 to FIG. 32, the buried contact BC is formed.

The buried contacts BC may be formed in each of the plurality of isolated areas that are spaced from each other. For example, a plurality of second mask patterns 320 may be formed on the first area I and the second area II. The plurality of second mask patterns 320 may be spaced apart from each other in the first direction Y and may extend in a parallel manner to each other and in the second direction X and may be arranged side by side. Subsequently, an etching process on the pre-contact film pBC may be performed using the plurality of second mask patterns 320 as an etching mask, so that a plurality of fence trenches 170t may be formed. Adjacent ones of the plurality of buried contacts BC arranged along the first direction Y may be spaced from each other via each of the plurality of fence trenches 170t arranged along the first direction Y.

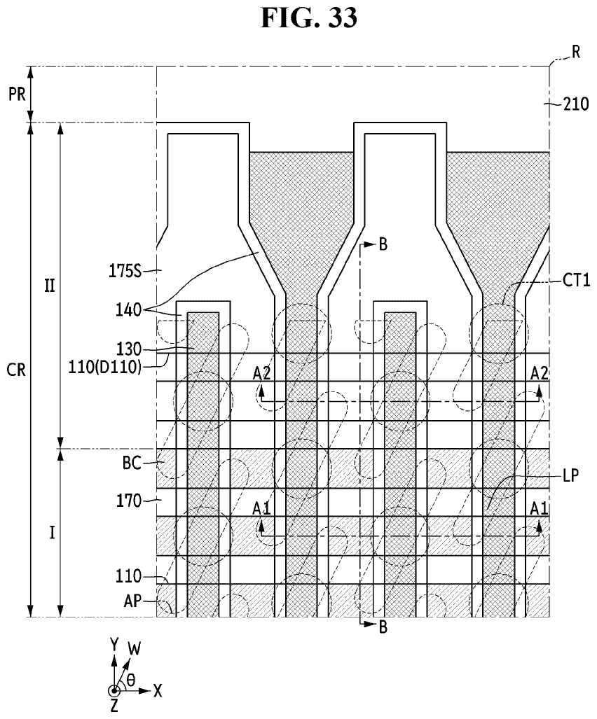

Referring to FIG. 33 to FIG. 3l , the fence insulating film 170 is formed.

The fence insulating film 170 may fill the fence trench 170t. Thus, the bit-line structures BLS and the fence insulating films 170 may define the plurality of isolated areas arranged in the lattice structure. The buried contacts BC may be respectively formed within the isolated areas and may be spaced from each other.

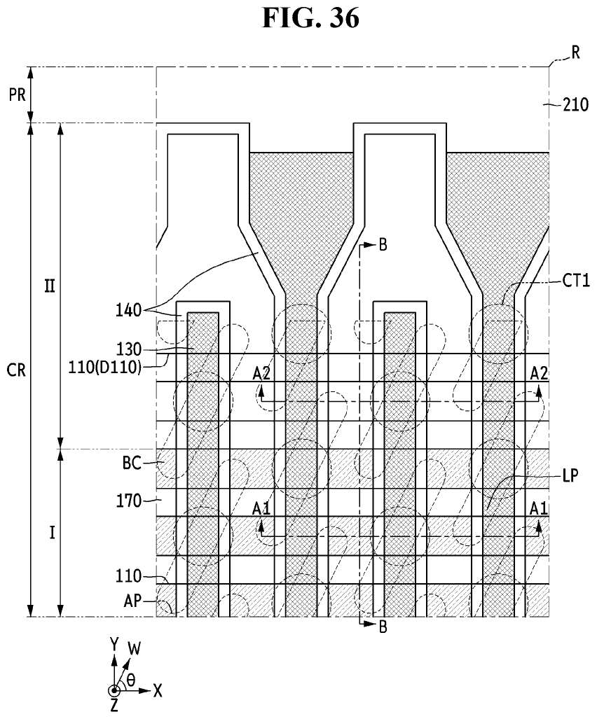

Referring to FIG. 36 to FIG. 38, the sacrificial film 175S is removed.

The sacrificial film 175S may be selectively removed from the bit-line structure BLS, the buried contact BC, and the fence insulating film 170. As the sacrificial film 175S is removed, a portion of the bit-line structure BLS on the second area II may be exposed.

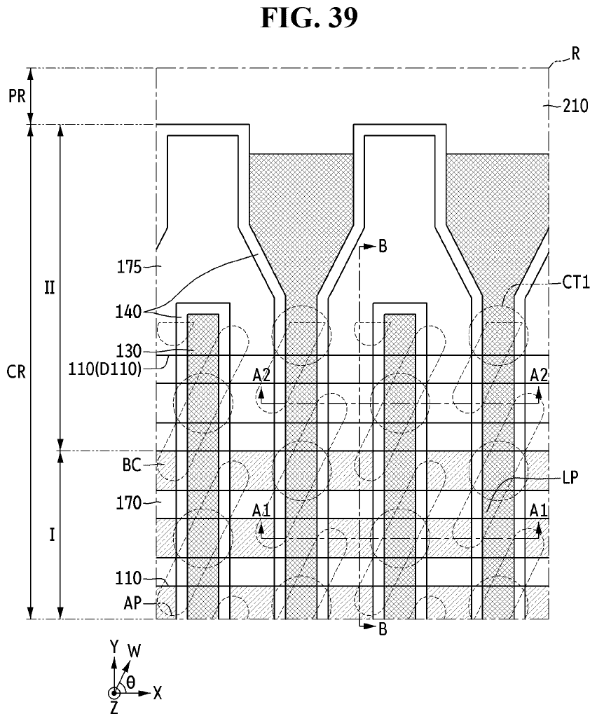

Referring to FIG. 39 to FIG. 41, the edge insulating film 175 is formed.

The edge insulating film 175 may be formed on the second area II of the substrate 100. The edge insulating film 175 may replace an area from which the sacrificial film 175S has been removed. Accordingly, the edge insulating film 175 extending along the end of the conductive pattern 130 may be formed.

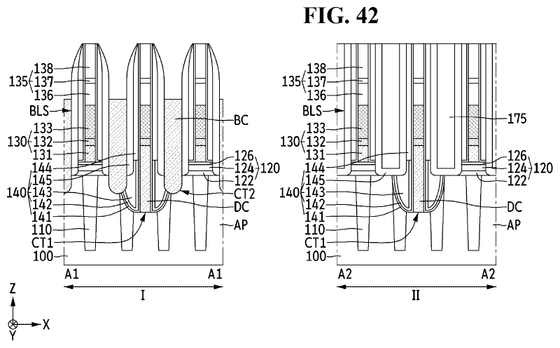

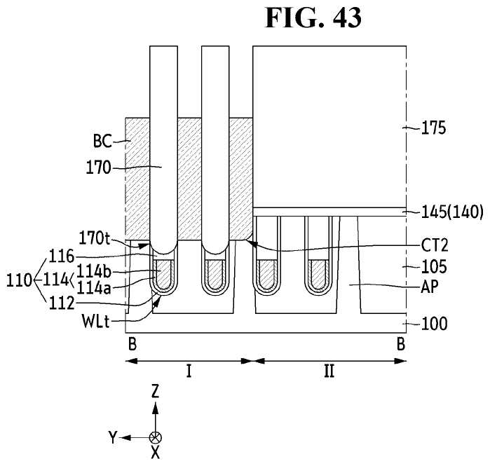

Referring to FIG. 42 and FIG. 43, an etch-back process is performed on the buried contact BC.

In the etch-back process, the buried contact BC may be selectively etched with respect to the bit-line structure BLS, the fence insulating film 170, and the edge insulating film 175. As the etch-back process is performed, an upper portion of the buried contact BC may be removed. For example, after the etch-back process is performed, the vertical level of the upper surface of the buried contact BC may be lower than the vertical level of the upper surface of the capping pattern 135.

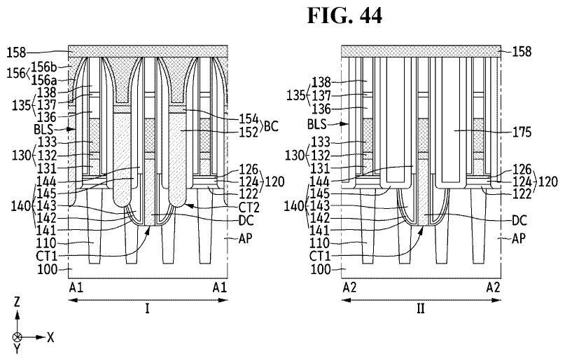

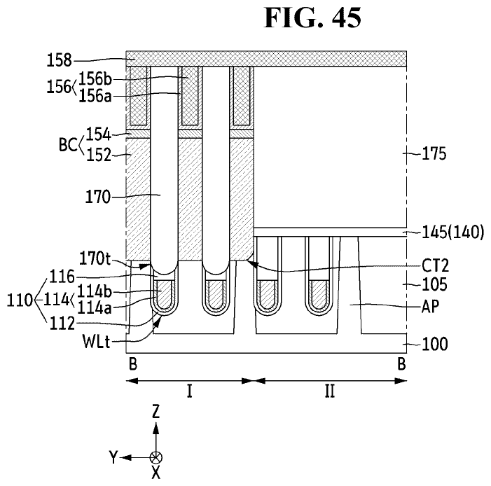

Referring to FIG. 44 and FIG. 45, the lower pad 156 and the upper pad 158 are formed.

The lower pad 156 may be formed on the first area I. The lower pad 156 may be formed on the upper surface of the buried contact BC and the side surface of the bit-line structure BLS. The lower pad 156 may be connected to the buried contact BC.

The upper pad 158 may be formed on the first area I and the second area II. The upper pad 158 on the first area I may extend along the upper surface of the lower pad 156, the upper surface of the bit-line structure BLS, and the upper surface of the fence insulating film 170. The upper pad 158 on the first area I may be connected to the lower pad 156. The upper pad 158 on the second area II may extend along the upper surface of the bit-line structure BLS and the upper surface of the edge insulating film 175.

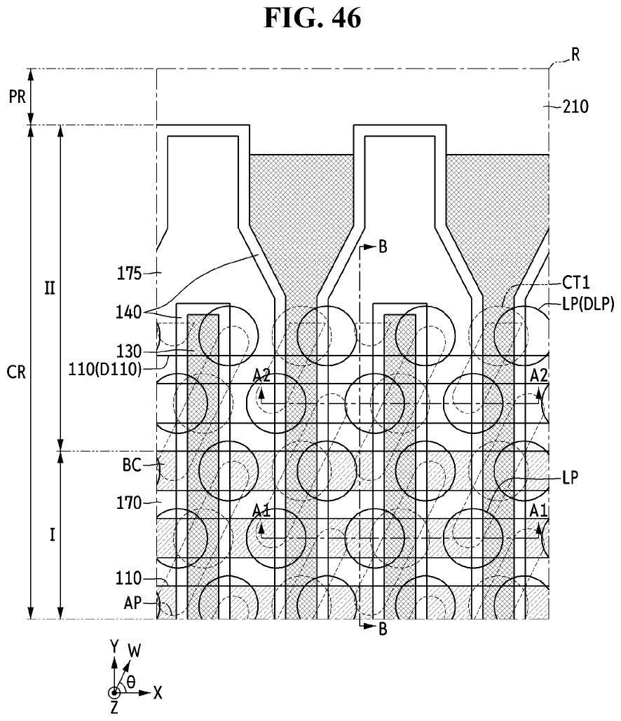

Referring to FIG. 46 to FIG. 48, the pad trench LPt is formed.

The pad trench LPt may be formed on the first area I and the second area II. A vertical level of the lower surface of the pad trench LPt on the first area I may be lower than the vertical level of the upper surface of the capping pattern 135 and may be higher than the vertical level of the upper surface of the conductive pattern 130. The vertical level of the lower surface of the pad trench LPt on the second area II may be lower than the vertical level of the upper surface of the edge insulating film 175. The landing pad LP may be formed in each of the plurality of isolated areas that are spaced from each other via the pad trench LPt.

Next, referring to FIG. 2 to FIG. 4, the isolation insulating film 180 and the capacitor structure 190 are formed. Thus, the semiconductor memory device as described above using FIG. 1 to FIG. 5 may be manufactured.

As the semiconductor memory device becomes increasingly highly integrated, individual circuit patterns are becoming smaller in order to implement a larger number of semiconductor memory devices in the same area. However, the miniaturization of the individual circuit patterns increases the process difficulty and causes defects. For example, during the manufacturing process of the semiconductor memory device, a pattern defect may occur at an end of the bit-line adjacent to the peripheral area. Such a pattern defect causes a bridge between the pattern and the conductive pattern (e.g., a dummy buried contact) formed adjacent thereto, thereby causing decrease in a yield and productivity of the semiconductor memory device.

In the semiconductor memory device according to some embodiments, the edge insulating film 175 may prevent the pattern defect that may occur at the end of the bit-line. Specifically, as described above, the edge insulating film 175 may extend along the end portion (e.g., the first edge portion E1 and the second edge portion E2) of the conductive pattern 130 to prevent the buried contact BC from being formed around the end portion of the conductive pattern. Thus, the bridge may be prevented from being formed between the end portion of the conductive pattern 130 and the buried contact BC, such that the semiconductor memory device with improved yield and productivity may be provided.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A semiconductor memory device comprising:
a substrate including a first area and a second area arranged along a first direction;
an active pattern disposed in the first area and including a first portion and a second portion;
a gate electrode extending in a second direction intersecting the first direction, the gate electrode crossing between the first portion and the second portion;
a conductive pattern disposed on the substrate and connected to the first portion, the conductive pattern extending in the first direction, and having an end on the second area;
a buried contact disposed on a side surface of the conductive pattern on the first area, the buried contact connecting to the second portion;
a capacitor structure connected to the buried contact; and
an edge insulating film disposed on a side surface of the conductive pattern on the second area, the edge insulating film surrounding the end of the conductive pattern.

2. The semiconductor memory device of claim 1, wherein the edge insulating film comprises:
a first filling portion overlapping the conductive pattern in the second direction; and
a second filling portion overlapping the conductive pattern in the first direction.

3. The semiconductor memory device of claim 2, wherein the edge insulating film includes a seam extending in the first direction within the first filling portion and extending in the first direction within the second filing portion.

4. The semiconductor memory device of claim 1, further comprising:
a fence insulating film overlapping the gate electrode in a third direction intersecting the upper surface of the substrate on the side surface of the conductive pattern on the first area.

5. The semiconductor memory device of claim 4, wherein the buried contact is interposed between the edge insulating film and the fence insulating film in the first direction.

6. The semiconductor memory device of claim 1, further comprising:
a spacer structure disposed between the conductive pattern and the buried contact and between the conductive pattern and the edge insulating film and extending along the side surface of the conductive pattern.

7. The semiconductor memory device of claim 6, wherein a portion of the spacer structure is interposed between the substrate and the edge insulating film.

8. The semiconductor memory device of claim 1, further comprising:
a landing pad disposed on an upper surface of the buried contact connecting the buried contact to the capacitor structure; and
a dummy landing pad disposed on an upper surface of the edge insulating film and spaced apart from the landing pad.

9. The semiconductor memory device of claim 1, wherein the edge insulating film comprises a silicon nitride film.

10. The semiconductor memory device of claim 1, wherein the substrate comprises a gate trench extending in the second direction and crossing between the first portion and the second portion,
wherein the gate electrode is buried in the gate trench.

11. A semiconductor memory device comprising:
a substrate including a first area and a second area arranged along a first direction;
an active pattern disposed in the first area and including a first portion and a second portion;
a gate electrode extending in a second direction intersecting the first direction, the gate electrode crossing between the first portion and the second portion;
a conductive pattern disposed on the substrate and connected to the first portion, the conductive pattern extending in the first direction, and having an end on the second area;
a spacer structure disposed on and extending along a side surface of the conductive pattern;
a buried contact disposed on the spacer structure on the first area, the buried contact connecting to the second portion;
a capacitor structure connected to the buried contact; and
an edge insulating film disposed on the spacer structure on the second area,
wherein a portion of the spacer structure is interposed between the substrate and the edge insulating film.

12. The semiconductor memory device of claim 11, wherein the edge insulating film comprises a seam spaced apart from the spacer structure.

13. The semiconductor memory device of claim 11, wherein the spacer structure comprises a first side spacer and a second side spacer sequentially stacked on the side surface of the conductive pattern,
wherein a portion of the second side spacer extends along an upper surface of the substrate in the second area to be disposed between the substrate and the edge insulating film.

14. The semiconductor memory device of claim 13, wherein the buried contact extends through another portion of the second side spacer in the first area to connect to the second portion.

15. The semiconductor memory device of claim 13, wherein the first side spacer comprises a silicon oxide film,
wherein the second side spacer includes a silicon nitride film.

16. A semiconductor memory device comprising:
a substrate including a cell area and a peripheral area around the cell area, wherein the cell area comprises a first area and a second area interposed between the first area and the peripheral area in a first direction;
an active pattern disposed in the first area and including a first portion and a second portion;
a gate electrode extending in a second direction intersecting the first direction, the gate electrode crossing between the first portion and the second portion;
a first conductive line disposed on the substrate and connected to the first portion, the first conductive line extending in the first direction;
a second conductive line disposed on the substrate and extending in the first direction, the second conductive line being spaced apart from the first conductive line in the second direction;
a buried contact disposed between the first conductive line and the second conductive line and connecting the second portion;
a capacitor structure connected to the buried contact; and
an edge insulating film disposed on the second area,
wherein the first conductive line comprises:
a first line portion disposed on the first area; and
a first edge portion disposed on the second area and having an end of the first conductive line,
wherein the second conductive line comprises:
a second line portion disposed on the first area; and
a second edge portion disposed on the second area and having an end of the second conductive line, the second edge portion protruding beyond the first edge portion toward the peripheral area,
wherein the edge insulating film comprises:
a first filling portion interposed between the first edge portion and the second edge portion in the second direction; and
a second filling portion overlapping the first edge portion in the first direction and overlapping the second edge portion in the second direction.

17. The semiconductor memory device of claim 16, wherein the edge insulating film comprises a seam extending in the first direction within the first filling portion, and extending in the first direction within the second filing portion.

18. The semiconductor memory device of claim 16, wherein the second edge portion comprises:
an extension portion overlapping the first filling portion in the second direction; and
an expansion portion overlapping the second filling portion in the second direction,
wherein a width in the second direction of the expansion portion is larger than a width in the second direction of the extension portion.

19. The semiconductor memory device of claim 18, further comprising a contact plug in contact with the expansion portion.

20. The semiconductor memory device of claim 16, wherein the edge insulating film is an integral element.
